(19) United States
(12) Patent Application Publication
(10) Pub. No.: US 2014/0262161 A1
(43) Pub. Date: Sep. 18, 2014

(54) METHOD AND APPARATUS FOR DYNAMICALLY COOLING ELECTRONIC DEVICES

(71) Applicant: David Lind Weigand, Cupertino, CA (US)

(72) Inventor: David Lind Weigand, Cupertino, CA (US)

(21) Appl. No.: 14/205,951

(22) Filed: Mar. 12, 2014

Related U.S. Application Data
(60) Provisional application No. 61/776,799, filed on Mar. 12, 2013.

(51) Int. Cl. H05K 7/20

(52) U.S. Cl. CPC H05K 7/20272
USPC 165/104.33

(57) ABSTRACT

This invention provides a method and apparatus for device designers to overcome such limitations by incorporating a dynamic fluid cooling system to transfer heat within the device amongst various subsystems and convect the heat externally, versus current static thermal solutions which conductively spread heat in a limited manner at significant cost. Specifically these dynamic fluid cooling methods and apparatus for electronic device enable increased performance and decreased cost across many of the device subsystems including but not limited to: electronics, integrated circuits, batteries, display panels, touch panels, lighting, audio transducers, imaging, flash LEDs and chargers.

### RELATED APPLICATIONS

This application his application claims priority to and the benefit of U.S. Patent Application 61/776,799, entitled “Method and Apparatus for Dynamically Cooling Electronic Devices,” which was filed on Mar. 12, 2013, the disclosure of which is incorporated herein by reference.

### BACKGROUND OF THE INVENTION

The invention relates to various methods and apparatus for dynamic fluid cooling electronic devices and their subsystems. Currently those skilled in the art understand electrical devices are heavily restricted in performance due to thermal limitations which greatly impact device operating performance, power consumption, battery life, power delivery, device costs, device size and device thermal safety concerns.

### DESCRIPTION OF THE INVENTION

This invention provides a method and apparatus for device designers to overcome such limitations by incorporating a dynamic fluid cooling system to transfer heat within the device amongst various subsystems and convect the heat externally, versus current static thermal solutions which conductively spread heat in a limited manner at significant cost. Specifically these dynamic fluid cooling methods and apparatus for electronic device enable increased performance and decreased cost across many of the device subsystems including but not limited to: electronics, integrated circuits, batteries, display panels, touch panels, lighting, audio transducers, imaging, flash LEDs and chargers.

### BRIEF SUMMARY OF THE INVENTION

An exemplary embodiment of an electronic device comprising this dynamic fluid thermal cooling technology entails various methods, apparatus and topologies to transfer, control and circulate thermal cooling fluid within an electronic device and its subsystems. Several implementations of dynamic fluid cooling architectures and topologies are described by using fluid conduits, heat exchangers, mesh conduit structures, fluid valves, reservoirs, manifolds, thermal plates, midframes, housings, radiators, heat sinks, air disturbers, etc. along with device elements such as thermistors, gyroscopes, accelerometers, imagers, barometers, proximity detectors, SAR detectors, oximeters, bio-sensors, ambient light sensors, power sensors and other integrated device sensors to most effectively dynamically cool the device and its critical performance subsystems.

It is envisioned that electronic devices across a plethora of product segments can leverage the dynamic fluid thermal cooling apparatus technology. Any devices that have a thermal heating concern can benefit from this technology. These devices are comprised of but not limited to: cell phones, tablets, phablets, TVs, notebooks, clamshells, set top boxes, TV boxes, compute glasses, watches, portable electronic devices, auto infotainment systems, auto cluster gauges, aircraft instrumentation, DVD players, MP3 players, AIO (All-in-one) computer consoles and consumer electronic devices. It is also envisioned that software can maintain a history of device orientation and human proximity events so the electronic device learns how it is typically used, oriented and held so the software can optimally control the dynamic cooling configuration.

### BRIEF DESCRIPTION OF THE DRAWINGS

This invention can be more fully and clearly understood by reading the subsequent detailed descriptions and examples with reference made to the following accompanying drawings, wherein:

FIG. 1, is a sectional side view, of a midframe heat exchanger cooling topology wherein the cooling apparatus utilize a pump and optional valve system to circulate cooling fluid.

FIG. 2, a sectional side and top view, provides an alternate view of the midframe heat exchanger topology focusing on the electronic component topology and battery, excluding the pump and valve. The top view illustrates an example of the midframe cooling channel mesh topology.

FIG. 3, a sectional side view, depicts a preferred embodiment of a dual midframe heat exchanger architecture encasing a PCB with electrical components and subsystems, excluding the pump and valve(s). In an alternate embodiment the hybrid dynamic fluid thermal cooling architecture is shown below.

FIG. 4, is a sectional side view, of a plethora of networked fluid reservoirs heat exchanger cooling topology wherein the cooling apparatus utilize a pump and optional valve system to circulate cooling fluid.

FIG. 5, is a sectional side view which uses a dual fluid reservoir dynamic thermal cooling architecture.

FIG. 6, is a sectional side view which depicts a dynamic fluid cooling topology for a processor with a Package-On-Package (POP) architecture.

FIG. 7, a perspective front top and side view, depicts the thermal fluid conduit mesh in the outer surface ‘skin’ of the electrical device chassis that act as the thermal radiator to emit the heat from the electronic device.

FIG. 8, is a perspective back and side view, similar to FIG. 7, depicting the thermal fluid radiating conduit mesh can be placed throughout the chassis including the front panel, front bezel, rear chassis, top edge (side), bottom edge, left edge and right edge of the chassis with surface interconnects.

FIG. 9, is a perspective top and front view, depicting a similar example of a thermal fluid conduit mesh in the outer surface ‘skin’ of the chassis of the electrical device, specifically a phone.

FIG. 10, a perspective back, top and bottom view, similar to FIG. 9, depicts the thermal fluid radiating conduit mesh can be placed throughout the chassis including the front panel, front bezel, rear chassis, top edge and bottom edge with surface interconnects.

FIG. 11, a perspective front, side and back view, depicts a device with dynamic Orientation thermal cooling architecture leveraging the Accelerometer and Gyroscope in conjunction with several thermistors and other sensors to optimize thermal cooling of the electronic device based on electronic device orientation and movement.

FIG. 12, a perspective front, side and back view, depicts a device with dynamic Proximity thermal cooling architecture leveraging various proximity sensors, Specific Absorption Radiation (SAR), Imager, Automatic Light Sensor (ALS), oximeters and other bio-sensors and proximity sensors in conjunction with several thermistors to optimize thermal cooling of the electronic device based on human proximity to the electronic device.

FIG. 13, perspective rear and side view, illustrates how this dynamic fluid cooling technology can be leveraged to cool the battery and other subsystems to significantly improve battery performance, improve power efficiency and operating lifetime.

FIG. 14, a perspective front and side view, depicts a dynamic thermal display panel cooling topology to enable solar loading cooling and cooling for other environmentally induced thermal heating scenarios.

FIG. 15, a perspective side and back view, details an active convector dynamic orientation and proximity based fluid cooling system comprising radiators, heat sinks and air disturbers.

FIG. 16, a perspective side and back view, details another active convector dynamic orientation and proximity based fluid cooling system implemented in a phone type device comprising radiators, heat sinks and air disturbers.

### DESCRIPTION OF SPECIFIC EMBODIMENTS

While the following invention is described by way of several examples and in terms of the preferred embodiments, it is to be understood that the invention is not limited to the disclosed preferred embodiments. To the contrary, it is intended to cover various modifications, adaptations and similar arrangements, as would be apparent to those skilled in the art. Therefore, the scope of the following embodiments should be accorded the broadest interpretation so as to encompass all such modifications, adaptations, variations and similar arrangements.

FIG. 1, a sectional side view, exemplifies a cross section of the dynamic fluid thermal cooling apparatus for an electronic device. The electronic device is comprised of many critical thermal electrical components such as processors 1, memory 2, Power Management Unit (PMU) 3, modems 2, chargers 3, optical projection drivers, wireless communications 2, audio transducers, display drivers, touch 4, imagers, backlight LED drivers and wireless chargers mounted on the device's Printed Circuit Board (PCB) 12, as well as batteries 13, display panels 4, backlight LEDs 3, touch panels 4 and imaging subsystems integrated in the device chassis. It is understood there are many other thermal components in electrical devices not detailed here that this also applies to. This dynamic fluid cooling apparatus architecture is designed to thermally protect the electrical components and subsystems while dispersing the thermal energy over the complete electronic device and optimizing the overall electronic device thermal profile. Optimal dynamic cooling of the electrical components also increases their performance and reduces overall device power. This yields a higher performing electronic device at an overall lower device skin temperature with significantly less thermal device skin gradients, consuming less power and therefore operating longer with greater performance on the same battery. This dynamic fluid thermal cooling solution uses the midframe heat exchanger 5 structure with an internal fluid mesh channel 6 to absorb heat from the electrical components while the electrical device is operating. The fluid pump 7 moves the fluid thru the mesh channels 6 in the midframe 5, absorbing heat from all the critical electrical components, efficiently transferring the heat to the fluid and circulating the fluid thru the radiating conduit mesh 14 in the chassis 19 of the electrical device. The dynamic advection based thermal cooling system is controlled by software which uses several thermistors 8 and other sensors in the system to control the pump speed, duty cycle and fluid direction, in a feedback control loop, so the fluid flow rate is optimally controlled to absorb heat in the midframe heat exchanger 5 from the electrical components and efficiently radiate the heat in the fluid in the mesh conduit 14 in the device chassis 19 and other device radiators and heat sinks integrated in the chassis 19 at the lowest pump power. Additionally, it is understood the dynamic fluid cooling system software can also use a priori knowledge of the power that each electronic device is being supplied with, based on the current operating mode of the device, to control the cooling fluid flow in a feed forward control loop. The fluid in the radiating conduit mesh 14 can be optionally controlled by various fluid valves 9 to balance the fluid flow and hence the thermal radiation thru the chassis which controls the chassis 19 temperature and device profile. The chassis temperature must be carefully controlled and monitored due to safety reasons for human interaction. Since the human body can touch this device anywhere on the chassis it is critical that the device meets all the thermal safety device specifications. It is also conceivable that this dynamic fluid based thermal cooling closed system can be architected in such a way that buoyancy forces enable autonomous fluid circulation; hence, pumps 7 and/or valves 9 are not required to operate this closed thermal fluid cooling system. It is also understood to those skilled in the art that there are many types of pumps 7 that can optimally satisfy these device requirements for low power, small size, low cost, light weight, efficiency and optimal variable flow rate as well as other methods of injecting, propelling, squeezing, impelling or driving liquid thru the heat exchanger 5 and the radiating conduit mesh 14 in the device chassis. As shown in FIG. 1 the cooling topology is tightly integrated with the electromagnetic interference (EMI) metal shield cans 10 with thermal interface material (TIM) 11 surrounding each electronic device and each shield can 10 enclosure. It is understood by those skilled in the art why shielded enclosures are required and used in electronic devices; specifically those with RF emission sources. As shown, these electronic devices may or may not have an EMI shield 10 enclosures on various electronic components and the electronic components can be efficiently thermally coupled to the thermal midframe heat exchanger 5 in either case by stepping or recessing the midframe over the electrical components to enable optimal thermal contact. It is also possible to use an EMI fence type shield 10 which makes electrical contact between the PCB 12 and midframe 5 so the stepped or recessed midframe can directly thermally contact the electronic components while still enabling required EMI isolation. The midframe heat exchanger 5 structure also efficiently couples the battery 13 for effective cooling. Cooling the battery 13 greatly improves the battery charging and discharge capability and extends the battery's calendar life as will be further discussed later.

FIG. 2, a sectional side and top view, exemplifies one embodiment of the heat exchanger fluid mesh channels 6 in the midframe 5. The midframe 5 may be a heat exchanger construction design that may have micro-fins, baffles, ridges to control the fluid flow within the heat exchanger and corrugated features in the fluid channels 6 to create turbulence to increase surface area for more efficient thermal transfer to the fluid. The midframe 5 in one embodiment may be a plate type heat exchanger as someone skilled in the art would understand. There are many mesh channels 6 patterns that can be used in the midframe heat exchanger 5 based on the specific thermal requirements and design of the device. These patterns do not need to be spatially uniform and will actually have higher concentration of fluid mesh channels 6 in thermally intense areas to enable optimal heat exchange by the midframe 5. More than one input and one output fluid conduit 15 connected to the heat exchanger midframe 5 mesh channels 6 certainly may be envisioned. Additionally, this midframe 5 heat exchanger may not have a planar mesh channels 6 but may be 3-D, especially in areas where the heat exchanger is stepped to contour to the profile of the electrical components and subsystems, to allow optimal thermal transfer properties. The midframe heat exchanger 5 can also provide mechanical structural device integrity so it does not add any weight to the device and may be constructed out of any number of materials such as copper, aluminum, magnesium, stainless steel, etc. or any of their alloys. Since many electronic devices currently use such a midframe 5 for mechanical rigidity the fluid mesh channel 6 voids may actually reduce overall device weight. Since the midframe 5 is an integral component of the device it interfaces rigidly to the surface chassis 19 of the device; hence fluid conduits 15 can interface directly from the midframe heat exchanger 5 to the side frame chassis material which can be a plethora of materials including Poly Carbonate, ABS plastic, Nylon, Aluminum, Magnesium, Steel, etc. and may be molded, forged, stamped or extruded by many well known processes. It is also envisioned that the midframe heat exchanger 5 may use flexible or rigid fluid conduit 15 or tubing to interconnect it to the chassis. Both of these connection options are shown in FIG. 1. The thermal characteristics, W/mK and fluid thermal transfer conductivity should be heavily considered when selecting the midframe heat exchanger 5 material and construction. The same thermal consideration should be given to the thermal fluid.

FIG. 3, a sectional side view, depicts a preferred embodiment of a dual midframe 5 heat exchanger architecture encasing a PCB 12. In this top illustration the PCB 12 is double sided but this architecture is viable for both double sided and single sided PCBs 12. In this embodiment the upper midframe 5 and lower midframe 5 heat exchanger structures essentially sandwich the PCB 12 and electrical components. Both upper and lower midframes 5 can be stepped and recessed to thermally contact the variable height electronic components using EMI fence shields 10 as described in FIG. 1. As illustrated in the top example in FIG. 3 the midframes 5 can also be constructed to have the exact 3-D skyline profile of the PCB 12 and all electronic components including the subsystems such as battery 13, etc. This will allow the PCB 12 to precisely fit into the midframe heat exchangers 5, and the midframe heat exchangers 5 together create a clamshell around the PCB 12. TIMs 11 are used on the thermal interfaces between the PCB 12 and both midframe heat exchangers 5. Thin conductive strips can be used on the midframes 5 to contact ground traces on both sides of the PCB 12 so the midframe 5 also acts as the EMI shield 10. This is well known to those skilled in the art. The midframes 5 are both an integral component of the device so they interface rigidly to the chassis 19 of the device; hence fluid conduits 15 can interface directly from the midframe heat exchanger 5 to the fluid mesh conduits 14 in the side frame chassis 19. The midframe 5 fluid mesh channels 6 in both midframes can be joined together as one large heat exchanger driven off one pump 7 or it can be envisioned they can operate separately and operate off separate pumps 7. The dual midframe heat exchanger 5 thermal cooling system is controlled by software which uses several thermistors 8 and other sensors in the system to control the pump 7, or pumps 7, speed, duty cycle and fluid direction, so the fluid flow rate is optimally controlled to absorb heat in the midframe heat exchangers 5 from the electrical components and efficiently radiate the heat in the fluid in the mesh conduit 14 in the device chassis 19.

In an alternate embodiment the hybrid dynamic fluid thermal cooling architecture is shown in bottom of FIG. 3. Specifically this thermal fluid cooling architecture uses the heat exchanger midframe 5 combined with a fluid reservoir 16 heat exchanger on the bottom side of the PCB 12 to pull heat out of both top and bottom of the electronic components. This electronic component can be any integrated circuit, as described above or any subsystem of the electronic device including the battery 13, display panel 4, etc as defined previously. This bottom side fluid reservoir 16 heat exchanger does not need to be a fluid reservoir it can simply be a planar, or 3-D, fluid conduit 15 below the PCB 12 thermally bonded to a thermal plate 17 on the PCB 12 to enable efficient thermal transfer. The bottom side heat exchanger subsystem also has thermistors 8 and other sensors to provide thermal feedback. Software uses these and other device sensors to dynamically control the cooling system to determine the optimal flow rates thru both heat exchangers 5 so the heat transfer and heat movement within the device is optimal for the device components and the electronic device skin temperature and thermal radiation and disbursement.

FIG. 4 shows a sectional side view and an alternative method of the thermal cooling architecture using a heat exchanger apparatus that comprises a plethora of fluid reservoirs 16 surrounding each thermally critical electrical component to enable efficient heat transfer. These fluid reservoirs 16 are sized and designed based on thermal requirements, flow rate and thermal capacity of the electronic component. FIG. 4 is a side view of the electronic device and the components are depicted in a straight line with a constant diameter fluid conduit 15 connecting the reservoirs 16 for illustrative interconnect purposes only. These electrical components are in 3-D space within the electronic device; hence the fluid conduits 15 can connect component reservoirs 16 in parallel, series or a mesh depending on the thermal requirements and flow rates required. Thermal fluid flow thru these component heat exchanging reservoirs 16 may be autonomous, leveraging fluid viscosity flow rate differentials, or may be controlled by valves 9 which are managed by software based on thermistors 8 as depicted in FIG. 4 near the various fluid reservoirs 16 and other sensors in the device. The interconnect conduit 15 can be constructed in variable cross-section and dimension. As shown in FIG. 4 the fluid reservoir 16 is tightly integrated with EMI shield enclosures 10. These component reservoirs 16 have thermistors 8 and other sensors to provide thermal feedback to enable software fluid dynamic cooling control. The reservoir 16 can be within the shield enclosure 10 directly thermally interfacing to the electronic component with a TIM 11. In this topology the fluid reservoir 16 is enclosed by the shield 10 which thermally interfaces to the device midframe as show in FIG. 4. Anyone skilled in the art will know the TIM 11 (Thermal Interface Material) can be a plethora of materials including thermal grease, graphite sheets, copper alloy, etc. Alternatively the fluid reservoir 16 can be outside the shield enclosure 10. In this embodiment the EMI shield 10 has a TIM 11 surrounding it as a thermal interface to the fluid reservoir 16. This allows the more traditional EMI shield 10 enclosure to be used. In this topology the fluid reservoir 16 thermally interfaces with the device's structural midframe 18. Alternatively, the fluid reservoir 16 can directly surround the electrical component with TIM 11 as a thermal interface and be directly coated with a silver paint on the outside surface and grounded to the PCB 12. This allows the fluid reservoir 16 to also act as the EMI shielding enclosure.

FIG. 5 is a sectional side view which uses a dual reservoir dynamic thermal cooling architecture. Specifically this dual reservoir thermal cooling topology uses two fluid reservoir 16 heat exchangers on the bottom side and top side of the PCB 12 to pull heat out of both top and bottom surfaces of the electronic components. This electronic component can be any integrated circuit, as described above or any subsystem of the electronic device including the battery 12, display panel 4, etc as defined previously. This bottom side heat exchanger does not need to be a fluid reservoir 16 it can simply be a planar, or 3-D, fluid conduit 15 configuration below the PCB 12 thermally bonded to a thermal plate 17 on the PCB 12 to enable efficient thermal transfer. The bottom side reservoir 16 heat exchanger subsystem also has thermistors 8 and other sensors to provide thermal feedback. Software uses these and other device sensors to dynamically control the cooling system to determine the optimal flow rates thru both fluid reservoir 16 heat exchangers so the heat transfer and heat movement within the device is optimal for the device components, the electronic device skin temperature, and thermal radiation and disbursement.

FIG. 6 is a sectional side view which depicts a dynamic fluid cooling topology for a processor with a Package-On-Package (POP) 20 architecture. This package architecture is heavily used in the mobile space since it saves PCB 12 area but it has specific thermal problems since the heat is trapped in the POP processor 20, on the bottom of the POP stack, by the memory package which is stacked on top. The POP package 20 has an air gap 21 in between the two POPed packages which is a thermal barrier, and thermally insulates the processor on the bottom of the POP package stack. By encompassing this POP processor 20 in a fluid reservoir 16 as depicted in FIG. 6 the thermal fluid can flow between the packages, thru the air gap, and directly absorb heat from the processor package 20; thereby cooling it. The fluid reservoir 16 can be constructed such that the primary fluid passage is between the POP packages to further force cooling. Additionally, as depicted in FIG. 6 it is possible to employ the dual reservoir dynamic thermal cooling architecture. As described in FIG. 5 above, the dual reservoir thermal cooling topology uses two fluid reservoir 16 heat exchangers on the bottom side and top side of the PCB 12 to pull heat out of both top and bottom surfaces of the POP processor 20. The top and bottom side fluid reservoir 16 heat exchangers also have thermistors 8 and other sensors to provide thermal feedback. Software uses these thermistors 8 and other device sensors to dynamically control the cooling system to determine the optimal flow rates thru both fluid reservoir 16 heat exchangers so the heat transfer and heat movement within the device is optimal for the device components and the electronic device skin temperature.

FIG. 7, a perspective front and side view, depicts the thermal radiating fluid mesh conduit 14 in the outer surface ‘skin’ of the electrical device chassis 19 that act as the thermal radiator to emit the heat from the device in a uniform manner. These radiating fluid mesh conduits 14 carry the thermal fluid from the heat exchangers and can have many different patterns depending on the chassis 19 design, material and thermal radiation requirements. The thermal fluid radiating conduit 14 mesh network can be placed throughout the chassis 19 including the front panel, front bezel, rear chassis, top edge (side), bottom edge, left edge and right edge of the chassis 19. The radiating fluid conduits 14 may have micro fingers to increase surface area for more efficient radiation in the skin of the chassis 19. The radiating fluid conduit 14 mesh network also has several thermistors 8 strategically located to sense the fluid temperature so software can dynamically control valves 9 and fluid pump flow rate to ensure uniform radiation and maintain uniform device skin temperature across the entire device. This is critical to correctly control for device safety by human contact. The radiating fluid conduit 14 mesh network is connected from the front panel to the sides and the rear chassis of the electronic device thru fluid conduits 15.

FIG. 8, perspective back and side view, similar to FIG. 7, depicts the thermal fluid radiating conduit 14 mesh network can be placed throughout the chassis 19 including the rear chassis 19 and all sides of the chassis 19. The radiating fluid mesh conduit 14 on the rear of the chassis 19 is for illustration purposes and be a plethora of patterns depending on the chassis 19 materials and thermal requirements. The radiating fluid conduit 14 mesh network is connected from the front panel to the sides and the rear chassis of the electronic device thru fluid conduits 15.

FIG. 9, a perspective top and front view, depicts a similar example of a thermal fluid conduit 14 mesh in the outer surface ‘skin’ of the chassis 19 of the electrical device. Specifically this device is a form factor of a phone so the typical high human touch areas are on the long edges and long bezel of the panel area where one's hand wraps around the device, so there are no fluid conduit 14 radiators depicted in this area. It's obvious if radiating conduits 14 are desired in these high touch areas they can easily be added to those areas.

FIG. 10, a perspective back, top and bottom view, similar to FIG. 9, shows the thermal fluid conduit 14 radiating mesh can be placed throughout the chassis 19 including the front panel, front bezel, rear chassis, top edge and bottom edge. As above, the conduit mesh network 14 has several thermistors 8 strategically located to sense the fluid temperature so software can dynamically control valves 9 and fluid pump flow rate to ensure uniform radiation and maintain uniform device skin temperature across the entire device. This is critical to control correctly for device safety when touched. In this embodiment the radiated heat from the fluid conduits 14 is targeted to the low human touch areas for safety reasons. The radiating fluid conduit 14 mesh network is connected from the back panel to the sides and the front chassis of the electronic device thru fluid conduits 15.

FIG. 11, a perspective front, side and back view, depicts a device fully covered by thermal fluid conduit 14 radiating mesh, front, rear and sides, in the outer surface ‘skin’ of the chassis 19 of the electrical device. In this architecture the Accelerometer 22 and Gyroscope 23 are used in conjunction with several thermistors 8 by software to control fluid valves 9 to direct thermal fluid to the low human touch areas of the electronic device based on device orientation. This ‘orientation based’ dynamic thermal cooling allows the low touch areas to have a higher skin temp since they are not being touched by humans. In this embodiment when the Accelerometer 22 and Gyroscope 23 detect the electronic device is in the vertical landscape position the software will know the device is not being held on the top and bottom long edges so software will direct fluid in the conduit 14 mesh to those areas to radiate heat. Furthermore since the device's orientation is detected by the Accelerometer 22, the software will target more fluid to the top edge of the electronic device, since this will simulate natural convection. Similarly if the Accelerometer 22 and Gyroscope 23 detect the electronic device is in the vertical portrait orientation the software will know the device is not being held on the top and bottom short edges so software will direct fluid in the conduits 14 to those areas to radiate heat. This orientation cooling capability also uses the Gyroscope 23 to detect when the electronic device is moving and how it is moving so software can dynamically direct fluid in the conduits 14 to those areas anticipated to become low touch area.

FIG. 12, a perspective front, side and back view, depicts a device fully covered by thermal fluid conduit 14 radiating mesh, front, rear and sides, in the outer surface, ‘skin’, of the chassis 19 of the electrical device. In this architecture the various sensors in the proximity sensor suite are used in conjunction with several thermistors 8 by software to control fluid valves 9 that direct thermal fluid to the low human touch areas of the electronic device based upon real-time proximity to human touch. Specifically the sensors in the proximity sensors suite are comprised of, but not limited to, Automatic Light Sensor (ALS) 25, Proximity sensor 24, Imager 32, oximeters and Specific Absorption Radiation (SAR) 26. This proximity sensor suite enables direct, real-time detection of human proximity so software can dynamically control the fluid valves 9 to direct thermal radiating fluid away from the detected human proximity areas of the electronic device. The preferred embodiment for dynamic fluid cooling is using both orientation and proximity technologies together with thermistors 8 to directly detect human proximity, anticipate movement with the gyroscope 23 and use the accelerometer 22 to detect device orientation so software will target radiating fluid flow to the optimal surface to enhance natural convection of the electronic device. It is also envisioned that software can maintain a history of device orientation and proximity events so the electronic device learns how it is typically used, oriented and held so the software can optimally control the dynamic cooling configuration.

FIG. 13, perspective rear and side view, illustrates how this dynamic fluid cooling technology significantly improves battery 13 performance, improves power efficiency and operating lifetime. Both the midframe heat exchanger 5 topology, FIG. 1, and the fluid reservoir heat exchanger 16 topology, FIG. 4, can be leveraged to reduce the temperature of the battery. However, dual sided battery cooling is preferred which is probably implemented with minimal device thickness impact with the midframe heat exchanger 5 architecture, shown in FIG. 1, and the associated thermistors 8. Cooling Lilon batteries greatly improves the battery charging rate and discharge capacity and extends the battery's calendar life. By cooling the battery it can now be charged when it would not have been able to be charged without cooling due to high ambient battery temperature within the electronic device. In the battery 13 cooling topology in FIG. 13, software can control the cooling fluid flow rate to the fluid conduit mesh 14 and the midframe heat exchanger 5 around the battery 13 via valves 9 and thermistors 8 so software can focus more fluid to the battery area, thereby cooling the battery 13 more when in rapid charging or discharging modes.

FIG. 14, a perspective front and side view, depicts a dynamic thermal display panel 4 cooling topology to enable solar loading cooling. When electronic devices with display panels 4 are used outside in the direct sun the display panel 4 gets very hot from a combination of solar heating as well as internal display panel 4 heat and thermal energy from the electronic device. The display 4 can get quite hot to the human touch and the high thermal temps over time can damage, color shift and yellow the display panel 4. As shown in FIG. 14 the thermal fluid conduit 14 channels routed in the display panel 4 cover glass/acrylic can efficiently cool the panel 4 when software enables the fluid flow via the valves 9, as shown in FIG. 14, based on the thermistors 8 located as shown in FIG. 14. The software programmable pump 7 flow rate can keep the display panel 4 at a safe temperature. This topology keeps the display panel 4 safe for human touch and keeps the display panel 4 from being damaged. It is also understood that this thermal device cooling concept can thermally cool an electronic device due to general environmentally induced thermal heating. If any portion of the electronic device is being heated by the environment, such as hot air flow, sun, etc., the thermistors 8 detect the selective thermal event in the device and software can enable fluid flow in the thermally affected area which will equalize the temperature over the electronic device. In this case the fluid conduits 14 mesh in the thermally impacted area act as heat absorbers and move the heat to other cooler areas of the device.

FIG. 15, a perspective side and back view, details an active convector dynamic orientation and proximity based fluid cooling apparatus. Specifically in this embodiment the thermal cooling fluid conduits 15 are used to transfer heat from the thermally critical electrical components and subsystems in the electronic device to a convector, radiator or heat sink 27 located near a chassis opening, optionally with an air disturber 28 exhausting air thru the heat sink 27 as depicted in FIG. 15 and FIG. 16. The chassis opening in the electronic device can be a speaker grille 29, a vent grille 31 in the chassis 19, a parting line or some other concealed chassis 19 opening. These chassis 19 vent grills 31 can be on front, rear and all sides of the electronic device. The radiator or heat sink 27 should be thermally designed as a heat exchanging element that provides an efficient thermal interface between itself and the fluid in the fluid conduit 15 with a sufficient surface area and thermal design to dissipate the heat efficiently thru the chassis opening. The thermal characteristics, W/mK and fluid thermal transfer conductivity should be heavily considered when selecting the radiator or heat sink 27 material and construction. It is even feasible to run fluid micro conduits in the speaker grille, 30 or chassis vents grills, 31 itself as the radiating element as depicted in FIG. 15. There are many possible configurations and implementations of the radiator 27 integration into various speaker grilles 29 and vent grilles 31, covers and accesses, as those skilled in the art know and understand. Speakers grilles 29 are normally placed in a location on the device with minimal human contact and in such a manner that audio sound can always escape if the device is set on a table or flat surface, so speaker accesses are an excellent thermal escape since they are low touch and typically allow air flow. The various air disturber 28 technologies are well understood and can embody low cost, small size, light weight, low power and efficient implementations such as piezo fans and piezo blowers or in the case of using a speaker grille 29 it may be the speaker transducer itself. As demonstrated in FIG. 15 this active convector cooling can also use the accelerometer 22 and gyroscope 23 integrated in the electronic device as inputs to software to determine the orientation and movement of the electronic device. The software couples this with inputs from various integrated proximity sensors 24, as detailed previously, to detect human contact and human proximity so it can then control valves 9 to move the thermal fluid thru conduits 15 to the optimal radiator or heat sink 27 device or devices based on device orientation, movement and proximity and optionally enable the air disturber 28 to actively expel the heat outside the electronic device thru vents grills 31 and openings as previously discussed. Thermistors 8 mounted on the electronic device provide thermal feedback for software to control and optimize the dynamic fluid cooling system. This allows the device to radiate and even actively exhaust heat in an area where there is no human contact and the exhaust is optimally positioned in the device to induce natural convection cooling. It is envisioned that software can maintain a history of device orientation and proximity events so the electronic device learns how it is typically used, oriented and held so the software can optimally control the dynamic forced convective cooling configuration.

FIG. 16, a perspective side and back view, details another active convector dynamic orientation and proximity based fluid cooling system. Specifically this device is a form factor of a phone so the typical high human touch areas are on the long edges and long bezel of the panel area where one holds the device, so there are no fluid conduit 14 radiators depicted in this area. It's obvious if radiating fluid conduits 14 are desired in these high touch areas they can easily be added to those areas. The top and bottom thermal fluid conduit 14 topologies are simple illustrations of asymmetric implementation options. It is understood there are many fluid conduit 14 topologies and patterns that can be employed for different device structures and designs. In this architecture the Accelerometer 22, Gyroscope 23 and proximity sensors 24 are used in conjunction with several thermistors 8 by software to control the pump and the fluid valves 9 to direct thermal fluid to the heat sinks 27 in the low human touch areas of the electronic device based on device orientation and real-time human proximity detection. The air disturbers 28 located with the heat sink 27 can be separately enabled and speed controlled based on Accelerometer 22, Gyroscope 23 and proximity sensors 24 to actively exhaust heat thru the device chassis 19 speaker grills 29 or vent grills 31.

As depicted by FIG. 16 this dynamic fluid cooling technology enables cooling the ‘skin’ of the electronic device so it's safe for human touch while also directly cooling thermally sensitive internal electrical components to thermally protect them, improve their performance, increase their efficiency and reduce their power consumption. In addition to cooling the electronic components, batteries 13 and other subsystems this dynamic fluid cooling technology can also cool, but is not limited to, the speaker and speaker coils in the audio subsystem, optical projection components, display panel and imaging flash LEDs. It is understood by those skilled in the art how the fluid mesh conduits 14, meshes and thermistors 8 can be employed to cool these various subsystems and components. It is also understood that cooling of these components and subsystems is controlled by software and can be based on software's knowledge of device use case and operating conditions.

While this invention is described by way of several examples and in terms of the preferred embodiments, it is to be understood that the invention is not limited to the disclosed preferred embodiments. To the contrary, it is intended to cover various modifications, adaptations and similar arrangements, as would be apparent to those skilled in the art. Therefore, the scope of the embodiments should be accorded the broadest interpretation so as to encompass all such modifications, adaptations, variations and similar arrangements.

What is claimed is:

1. A fluid thermal cooling apparatus for an electronic device, comprising:
(a) an apparatus to transfer, control and circulate thermal cooling fluid within an electronic device and its subsystems, via
(b) a thermal fluid cooling topology with integrated circuit elements and fluid conduits and radiators integral to the device providing
(c) increased performance and decreased cost across many of the device subsystems including but not limited to: electronics, integrated circuits, batteries, display panels, touch panels, lighting, audio transducers, imagers, flash LEDs, sensors and chargers;
thereby enabling effective thermal cooling of the device and its critical performance subsystems.

2. A method of device thermal cooling based on dynamic, real-time device orientation and movement, comprising:
(a) providing Accelerometer, Gyroscope and other orientation based sensors possibly in conjunction with thermal sensors, controlled by software and hardware control mechanisms
(b) directing thermal cooling to the high human touch areas and optimal thermal dissipation configuration of the electronic device based on device real-time orientation
(c) providing for dynamic, real-time optimal thermal cooling based on movement of device and relative orientation cooling using the Gyroscope, Accelerometer and other orientation and device movement sensors detect when the electronic device is moving and how it is moving so software can dynamically direct thermal cooling fluid to those areas anticipated to become high human touch areas.

3. A method of thermal cooling based on dynamic real-time human proximity detection, comprising:
(a) providing the sensors in the proximity sensors suite are comprised of, but not limited to, Automatic Light Sensor (ALS), Proximity sensors, Imagers, Specific Absorption Radiation (SAR), oximeters and other proximity bio-sensors possibly in conjunction with thermistors and software/Hardware control mechanisms
(b) directing thermal cooling to the high human touch areas of the electronic device based on real-time human proximity of the device so software can dynamically direct thermal cooling fluid to those areas anticipated to become high touch areas wherein, device software can maintain a history of device orientation and human proximity events so the electronic device learns how it is typically used, oriented and held so the software can optimally control the dynamic cooling configuration.
